(19) United States
(12) Patent Application Publication
(10) Pub. No.: US 2024/0363458 A1
(43) Pub. Date: Oct. 31, 2024

(54) CIRCUIT CHIPS INCORPORATING NEGATIVE POISSON`S RATIO STRUCTURES

(71) Applicant: Joon Bu Park, Las Vegas, NV (US)

(72) Inventor: Joon Bu Park, Las Vegas, NV (US)

(21) Appl. No.: 18/309,408

(22) Filed: Apr. 28, 2023

(51) Int. Cl. H01L 23/15; H01L 23/14; H01L 23/29; H01L 23/48; H01L 25/065

(52) U.S. Cl. CPC H01L 23/15; H01L 23/147; H01L 23/291; H01L 23/481; H01L 25/0657; H01L 2225/06565; H01L 2225/06589

(57) ABSTRACT

A circuit chip includes a first body having a negative Poisson's ratio; a second body having a positive Poisson's ratio, wherein the first body and the second body are stacked on one another and thermally coupled to one another; and a first integrated circuit embedded in the second body.

### BACKGROUND

The present disclosure relates generally to circuit chips that incorporate structures having negative Poisson's ratios.

Circuit chips have integrated circuits that perform functions such as logic, sensing, and signal transmission/reception. For example, chips can include circuit elements such as transistors, diodes, and capacitors that perform circuit functions. As the density of circuit elements in circuit chips has increased, heat dissipation has emerged as a notable aspect of chip design.

### SUMMARY

We describe here circuit chips that feature negative Poisson's ratio (“NPR”) materials. The incorporation of NPR materials can provide various advantages over circuit chips that include only positive Poisson's ratio (PPR) materials. For example, in some implementations, NPR materials can facilitate improved heat dissipation from, and/or cooling of, integrated circuit(s) of the circuit chips. In some implementations, the NPR materials can allow the circuit chips to be lighter than PPR-only circuit chips. In some implementations, the NPR materials can provide improved mechanical and/or thermal stability based on comparative mechanical and/or thermal responses of the NPR materials and PPR portions of the circuit chips.

Some aspects of this disclosure describe a circuit chip including a first body having a negative Poisson's ratio, and a second body having a positive Poisson's ratio. The first body and the second body are stacked on one another and thermally coupled to one another. The circuit chip further includes a first integrated circuit embedded in the second body.

This and other circuit chips described herein can have one or more of at least the following characteristics.

In some implementations, the first body and the second body are rigid.

In some implementations, the first body includes a semiconductor, a glass, a ceramic, or a glass-ceramic.

In some implementations, the second body includes a silicon substrate or a printed circuit board.

In some implementations, the first body and the second body each have a substantially planar shape with a shortest dimension in a first direction, and the first body and the second body are stacked on one another in the first direction.

In some implementations, the circuit chip includes a metal pillar extending through the first body.

In some implementations, the metal pillar extends between the first body and the second body.

In some implementations, the circuit chip includes a metal heatsink thermally coupled to the metal pillar.

In some implementations, the circuit chip includes a second integrated circuit embedded in the first body.

In some implementations, the circuit chip includes a connector arranged to electrically couple the first integrated circuit and the second integrated circuit.

In some implementations, the circuit chip includes a third body having a positive Poisson's ratio. The first body is stacked between the second body and the third body.

In some implementations, the second body and the third body are formed of a common material.

In some implementations, the first body is porous.

In some implementations, the first body and the second body are in contact with one another.

In some implementations, the circuit chip includes a third body having a negative Poisson's ratio; and a fourth body having a positive Poisson's ratio. The third body and the fourth body are stacked on one another and thermally coupled to one another, and the first body and the second body are spaced apart from the third body and the fourth body. The circuit chip includes a second integrated circuit in the fourth body; and one or more connectors electrically coupling the first integrated circuit to the second integrated circuit.

Some aspects of this disclosure describe an electronic device including the circuit chip described above. The electronic device includes a smartphone, a computer, a tablet, a wearable devices, an Internet of Things device, a camera, a vehicle, or a drone.

Some aspects of this disclosure describe a circuit chip including a body having a positive Poisson's ratio; an integrated circuit embedded in the body; and a coating on the body, the coating having a negative Poisson's ratio.

This and other circuit chips described herein can have one or more of at least the following characteristics.

In some implementations, the coating includes a glass-ceramic having the negative Poisson's ratio.

In some implementations, the coating is porous.

In some implementations, the circuit chip includes a metal heatsink; and a metal pillar extending from the body, through the coating, and to the metal heatsink.

Other implementations are also within the scope of the claims.

### DESCRIPTION OF DRAWINGS

FIG. 1 is a diagram illustrating an example of a circuit chip incorporating an NPR body.

FIG. 2 is a diagram illustrating another example of a circuit chip incorporating an NPR body.

FIG. 3 is a diagram illustrating an example of a circuit chip that includes two units incorporating NPR bodies.

FIG. 4 is a diagram illustrating an example of a circuit chip incorporating an NPR coating.

FIG. 5 is a diagram illustrating the mechanical response of an NPR material.

FIGS. 6A-6C are diagrams illustrating the fabrication of an NPR body.

### DETAILED DESCRIPTION

This disclosure describes circuit chips that include materials having negative Poisson's ratios (“NPR materials”), sometimes referred to as auxetic materials. In some implementations, a circuit chip includes a first portion having a negative Poisson's ratio and a second portion having a position Poisson's ratio (formed of a “PPR material”). For example, the second portion can be an integrated circuit substrate or a printed circuit board, and the first portion can be another integrated circuit substrate or printed circuit board, and/or a coating on the second portion. The NPR composition of the first portion can facilitate reduced weight, improved mechanical stability (e.g., improved stress response), and/or improved heat dissipation/cooling of the circuit chip.

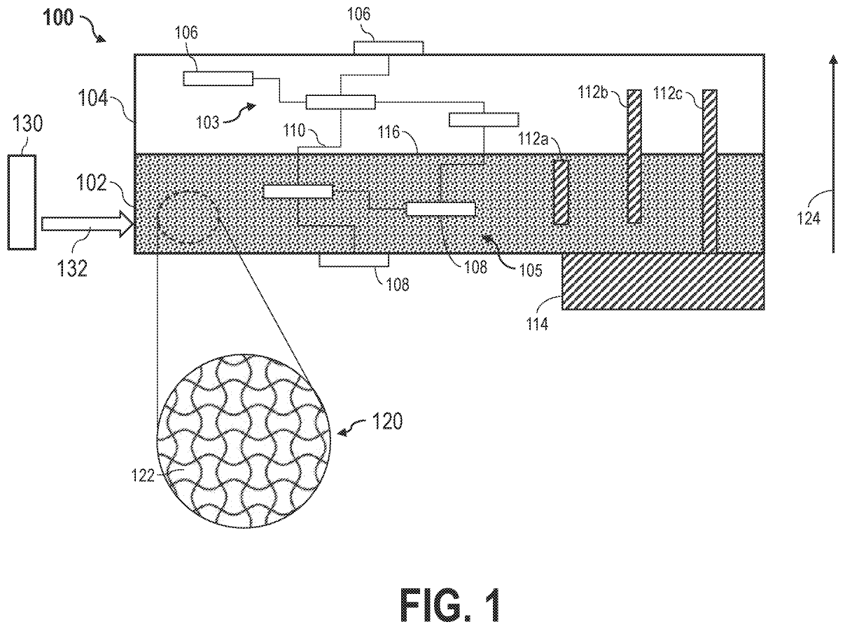

Referring to FIG. 1, an example of a circuit chip 100 includes a first body 102 having a negative Poisson's ratio, and a second body 104 having a positive Poisson's ratio. The first body 102 and the second body 104 are stacked on one another, e.g., with the second body 104 stacked on the first body 102 or the first body 102 stacked on the second body 104. In this example, the second body 104 is stacked on the first body 102, in a stacking direction 124, and in contact with the first body 102 at an interface 116. For example, the second body 104 can be bonded to the first body 102 and/or adhered to the first body 102 by one or more adhesives. In some implementations, one or more intervening layers are between the first body 102 and the second body 104.

In some implementations, each of the first body 102 and the second body 104 has a substantially planar shape, e.g., as a semiconductor wafer, semiconductor chip, or circuit board. In some implementations, as shown in FIG. 1, a shortest dimension of each of the first body 102 and the second body 104 (e.g., a dimension perpendicular to the substantially planar direction of extension of each of the first body 102 and the second body 104) is parallel to the stacking direction 124.

The circuit chip 100 further includes an integrated circuit 103 embedded in the second body 104. The integrated circuit 103 can include, for example, one or more circuit elements 106 disposed in and/or on the second body 104, such as one or more transistors, diodes, capacitors, and/or resistors. In some implementations, the integrated circuit 103 includes one or more computing devices such as processors, memories, and/or storage devices. In some implementations, the integrated circuit 103 includes one or more sensing devices (e.g., photodetectors and/or chemical detectors), one or more light-emitting devices (e.g., photodiodes and/or lasers), and/or one or more signal transmission, reception, and/or processing devices (e.g., a transceiver for RF transmission and reception). The integrated circuit 103, in various implementations, can include one or more of these and/or other types of devices. Circuit elements 106 of the integrated circuit 103 can be connected by interconnects, such as metal vias and metal traces.

The second body 104, which hosts the integrated circuit 103, can be rigid (e.g., formed of a semiconductor and/or a dielectric) or flexible (e.g., formed of a plastic). In some implementations, the second body 104 is a semiconductor substrate, such as a silicon substrate/wafer. In some implementations, the second body 104 is a silicon-on-insulator substrate. In some implementations, the second body 104 is a dielectric substrate, such as a sapphire substrate or a glass (e.g., silicon oxide) substrate. In some implementations, the second body 104 is a printed circuit board (PCB) (e.g., a FR-4 glass epoxy PCB), e.g., in which interconnects of the integrated circuit 103 are copper traces and the circuit elements 106 are soldered on a surface of the PCB.

The first body 102 has a negative Poisson's ratio, for example, a Poisson's ratio of between −1 and 0, such as between −0.8 and 0, e.g., −0.8, −0.7, −0.6, −0.5, −0.4, −0.3, −0.2, or −0.1. An NPR material is a material that has a Poisson's ratio that is less than zero, such that when the material experiences a positive strain along one axis (e.g., when the material is stretched), the strain in the material along the two perpendicular axes is also positive (e.g., the material expands in cross-section). Conversely, when the material experiences a negative strain along one axis (e.g., when the material is compressed), the strain in the material along a perpendicular axis is also negative (e.g., the material compresses along the perpendicular axis). By contrast, a PPR material has a Poisson's ratio that is greater than zero. When a PPR material experiences a positive strain along one axis (e.g., when the material is stretched), the strain in the material along the two perpendicular axes is negative (e.g., the material compresses in cross-section), and vice versa.

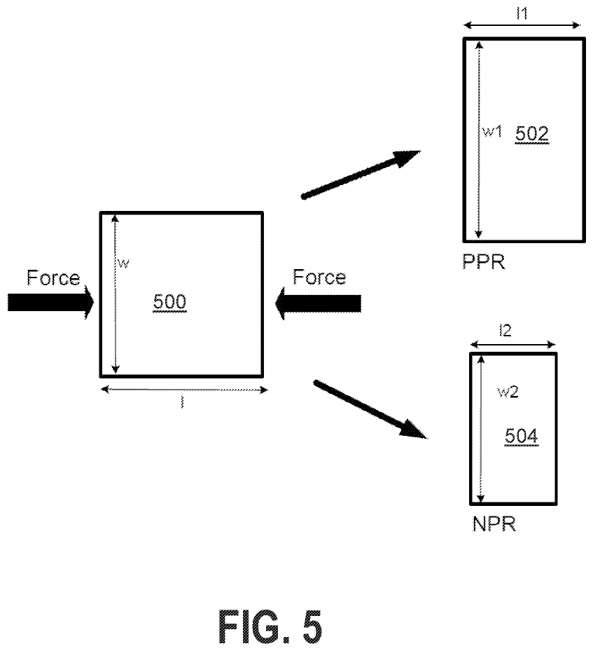

Materials with negative and positive Poisson's ratios are illustrated in FIG. 5, which depicts a hypothetical two-dimensional block of material 500 with length l and width w. If the hypothetical block of material 500 is a PPR material, when the block of material 500 is compressed along its width w, the material deforms into the shape shown as block 502. The width w₁ of block 502 is less than the width w of block 500, and the length l₁ of block 502 is greater than the length l of block 500: the material compresses along its width and expands along its length.

By contrast, if the hypothetical block of material 500 is an NPR material, when the block of material 500 is compressed along its width w, the material deforms into the shape shown as block 504. Both the width w₂ and the length l₂ of block 504 are less than the width w and length, respectively, of block 500: the material compresses along both its width and its length.

In some implementations, the first body 102 has a negative Poisson's ratio based on a microstructure of the first body. For example, the first body 102 can have a porous structure 120, as shown in the inset illustration of FIG. 1. The porous structure 120 has a cellular pattern that provides a negative Poisson's ratio (auxeticity) to the first body 102 as a whole. In some implementations, the porous structure 120 has a re-entrant lattice structure.

A foam is a multi-phase composite material in which one phase is gaseous and the one or more other phases are solid (e.g, polymeric, ceramic (e.g., a carbon-based ceramic), otherwise carbon-based, metallic, semiconducting, dielectric, or a combination thereof)). Foams can be closed-cell foams, in which each gaseous cell is sealed by solid material; open-cell foams, in which each cell communicates with the outside atmosphere; or mixed, in which some cells are closed and some cells are open.

An example of an NPR foam structure is a re-entrant structure, which is a foam in which the walls of the cells are concave, e.g., protruding inwards toward the interior of the cells, such as at least some of cells 122 of the porous structure 120 of FIG. 1. In a re-entrant foam, compression applied to opposing walls of a cell will cause the other, inwardly directed walls of the cell to buckle inward further, causing the material in cross-section to compress, such that a compression occurs in all directions. Similarly, tension applied to opposing walls of a cell will cause the other, inwardly directed walls of the cell to unfold, causing the material in cross-section to expand, such that expansion occurs in all directions. NPR foams can have a Poisson's ratio of between −1 and 0, e.g., between −0.8 and 0, e.g., −0.8, −0.7, −0.6, −0.5, −0.4, −0.3, −0.2, or −0.1. NPR foams can have an isotropic Poisson's ratio (e.g., Poisson's ratio is the same in all directions) or an anisotropic Poisson's ratio (e.g., Poisson's ratio when the foam is strained in one direction differs from Poisson's ratio when the foam is strained in a different direction).

An NPR foam can be polydisperse (e.g., the cells of the foam are not all of the same size) and/or disordered (e.g., the cells of the foam are randomly arranged, as opposed to being arranged in a regular lattice). An NPR foam can have a characteristic dimension (e.g., the size of a representative cell (e.g., average-size cell), such as the width of the cell from one wall to the opposing wall) ranging from 0.005 μm to about 3 mm, e.g., about 0.01 μm, about 0.02 μm, about 0.05 μm, about 0.1 μm, about 0.5 μm, about 1 μm, about 10 μm, about 50 μm, about 100 μm, about 500 μm, about 1 mm, about 2 mm, or about 3 mm, or any range delimited by any two of these values.

Examples of cell structures that can be realized on a macroscale or on a micro/nano scale in NPR bodies include stackings (e.g., ABAB or AAA stackings) of a quadratic chiral lattice, inverse honeycomb, double arrow, re-entrant hexagonal, re-entrant square, and other structures that can be identified by suitable computational and/or experimental methods. Example computational methods can be found in Körner and Liebold-Ribeiro, “A systematic approach to identify cellular auxetic materials,” Smart Materials and Structures 24 (2) (2015).

The first body 102 can be formed from the same material(s) as the second body 104 (e.g., with a different microstructure that provides the negative Poisson's ratio), and/or from different material(s). For example, in some implementations, the first body 102 is a porous semiconductor body having a negative Poisson's ratio, a porous glass and/or ceramic body (e.g., silicon oxide) having a negative Poisson's ratio, a porous glass-ceramic having a negative Poisson's ratio, or a porous polymer having a negative Poisson's ratio. The first body 102 can be rigid or flexible.

Examples of auxetic semiconductor materials (e.g., in a porous/foam form) for use in the first body 102 include silicon, germanium, and silicon carbide.

Examples of auxetic polymeric structures (e.g., in a porous/foam form) for use in the first body 102 include thermoplastic polymer foams (e.g., polyester polyurethane or polyether polyurethane); viscoelastic elastomer foams; and thermosetting polymer foams such as silicone rubber.

Examples of auxetic glasses and/or ceramics (e.g., in a porous/foam form) for use in the first body 102 include metal oxides (e.g., aluminum oxide, titanium oxide, or zirconium oxide), other oxides (e.g., silicon oxide, such as SiO2, or aluminum borosilicate), carbon, and hydroxyapatite.

Examples of auxetic glass-ceramics (e.g., in a porous/foam form) for use in the first body 102 include ZnO—Al2O3-SiO2, in some cases having one or more oxides (e.g., CaO, BaO and/or B2O3), the inclusion of which can alter thermal properties of the of the glass-ceramic. As another example, silicon oxycarbide glass-ceramics can be formed with an auxetic structure.

In some implementations, the first body 102 has a thermal expansion coefficient matching that of the second body 104, which can improve reliability of the circuit chip 100 in conditions of changing temperature.

The auxetic nature of the first body 102 can provide the circuit chip 100 with one or more beneficial characteristics. For example, the porous nature of the first body 102 can promote efficient cooling of/heat dissipation from the second body 104, e.g., to dissipate heat generated by operation of the integrated circuit 103. For example, the first body 102 can have a high surface area-to-volume ratio, e.g., compared to a body having the same chemical composition as the first body 102 but lacking the microstructure that provides the first body 102 with its negative Poisson's ratio. The high surface area-to-volume ratio facilitates rapid heat diffusion from the first body 102 to the surrounding medium, such as air or, in the case of a liquid-cooled computing arrangement, a liquid such as water or a coolant. Accordingly, heat generated by the integrated circuit 103 can transfer to the first body 102 and be efficiently dissipated by the first body 102 based on the porous nature of the first body 102. The first body 102 and the second body 104 can be thermally coupled to one another to facilitate the heat transfer, e.g., based on direct contact at the interface 116 and/or through one or more intervening layers.

Moreover, in some implementations, the pores of the first body 102 define channels through some or all of the first body 102. The medium in which the first body 102 is placed, such as air or a liquid, can flow through the channels, providing more rapid heat dissipation than if the medium were static. In some implementations, the flow is unpowered and natural, e.g., resulting from variations in temperature throughout the medium. In some implementations (e.g., any of the systems described with respect to FIGS. 1-4), a pump 130 is configured to cause flow of a fluid 132 (e.g., water or a coolant) through the channels of the first body 102, e.g., through a length or width of the first body 102. In some implementations, instead of or in addition to the pump 130, a fan is configured to cause airflow through the channels of the first body 102, to facilitate cooling.

NPR-PPR composite materials are composites that include both regions of NPR material and regions of PPR material. NPR-PPR composite materials can be laminar composites, matrix composites (e.g., metal matrix composites, polymer matrix composites, or ceramic matrix composites), particulate reinforced composites, fiber reinforced composites, or other types of composite materials. In some examples, the NPR material is the matrix phase of the composite and the PPR material is the reinforcement phase, e.g., the particulate phase or fiber phase. In some examples, the PPR material is the matrix phase of the composite and the NPR material is the reinforcement phase. NPR-PPR composite materials can form the porous structures and foam structures described in any of the implementations described herein. For example, in some implementations, the first body 102 is formed from an NPR-PPR composite material.

NPR bodies, having a structure such as the porous structure 120 of FIG. 1, can be produced in a variety of ways. In some implementations, an initially PPR material (sometimes referred to as a “precursor material”) is converted into the NPR material. For example, a porous PPR sponge or foam can be transformed to change its structure into a structure that exhibits a negative Poisson's ratio. In some examples, NPR foams are produced by transformation of nanostructured or microstructured PPR materials, such as nanospheres, microspheres, nanotubes, microtubes, or other nano- or micro-structured materials, into a foam structure that exhibits a negative Poisson's ratio. The transformation of a PPR foam or a nanostructured or microstructured material into an NPR foam can involve thermal treatment (e.g., heating, cooling, or both), application of pressure, or a combination thereof. In some examples, PPR materials, such as PPR foams or nanostructured or microstructured PPR materials, are transformed into NPR materials by chemical processes, e.g., by using an adhesive. In some examples, NPR materials are fabricated using micromachining or lithographic techniques, e.g., by laser micromachining or lithographic patterning of thin layers of material. In some examples, NPR materials are fabricated by additive manufacturing (e.g., three-dimensional (3D) printing) techniques, such as stereolithography, selective laser sintering, or other appropriate additive manufacturing techniques.

In an example of a process, a PPR thermoplastic foam, such as an elastomeric silicone film, can be transformed into an NPR foam by compressing the PPR foam, heating the compressed foam to a temperature above its softening point, and cooling the compressed foam. In an example, a PPR foam composed of a ductile metal can be transformed into an NPR foam by uniaxially compressing the PPR foam until the foam yields, followed by uniaxial compression in other directions.

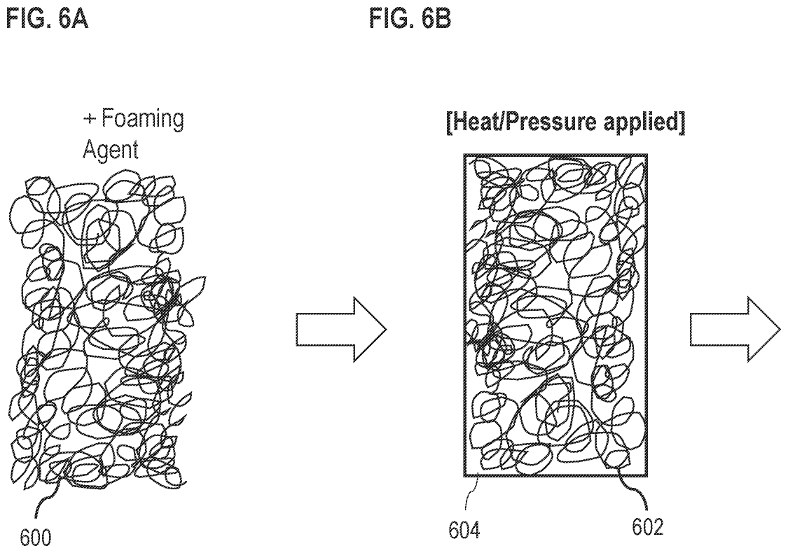

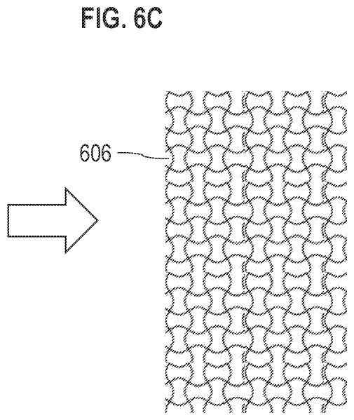

FIGS. 6A-6C illustrate an example method of making an NPR body of a circuit chip, such as the first body 102. A granular or powdered material 600 (a precursor material), such as a polymer material (e.g., a rubber), a ceramic, a glass, a semiconductor, or a glass-ceramic, or a combination thereof, is mixed with a foaming agent to form a porous material (e.g., a sponge or a foam) 602. The porous material 602 is placed into a mold 604. Pressure is applied to compress the porous material 602, and the compressed porous material 602 is heated to a temperature above its softening point. The compressed, heated porous material 602 is then allowed to cool, resulting in an NPR material 606 (in this example, having a closed-cell porous structure) produced from the initially-PPR porous material 602. The NPR material 606 can be bonded or otherwise adhered to the second body 104 as the first body 102.

Other methods of making an NPR body, such as various additive manufacturing (AM) methods, are also within the scope of this disclosure. Examples of AM methods include powder bed binder-jetting and resin-based stereolithography/digital light projection-based processes. In the case of powder bed binder-jetting, a precursor material, such as a ceramic, glass, glass-ceramic, or semiconductor, is made into a fine powder consistency. A layer of the powder is provided into a powder bed. An adhesive/polymer binder is deposited selectively in a determined cross-sectional shape onto the powder to provide structure, e.g., using an inkjet printer. The structure provides auxeticity to the material, e.g., based on a porous cell structure. After each layer, a dispenser deposits a fresh powder layer. After completion of printing, the printed structure undergoes a debinding/curing process in which the binder is pyrolized/burnt out of the structure (e.g., at an elevated temperature), leaving an NPR material.

In the case of resin-based printing, the ceramic, glass, glass-ceramic, or semiconductor powder is mixed with a photocurable resin to produce a slurry. The slurry is provided into a slurry bed, and a laser or other light source is used to selectively illuminate the slurry in a determined cross-sectional shape. For example, the laser can selectively scan across a surface of the slurry, or a light projector can illuminate the shape in a simultaneous flash. Photo-reactive compounds in the resin react with the light to locally cure the resin in the desired shape. The desired shape can be a porous structure that provides auxeticity. A wiper is swept across a surface of the slurry to provide a fresh coating, and the process repeats layer-by-layer. Post-processing can be performed to remove the resin.

As a further example, porous silicon, which in some implementations can be formed with a structure that provides a negative Poisson's ratio, can be fabricated by anodization, by stain-etching, or by bottom-up synthesis.

In some implementations, the first body 102 is formed on the second body 104. For example, the first body 102 can be formed by a bottom-up AM method starting at the interface 116. For example, the second body 104 can serve as a substrate on which the first body 102 is additively manufactured.

In some implementations, instead of or in addition to heat dissipation benefits provided by the first body 102, the combination of the first body 102 and the second body 104 can have beneficial mechanical and/or thermal response properties. The first body 102 and the second body 104 can mechanically behave oppositely to one another in response to a given force/pressure, e.g., expand/contract in orthogonal directions to one another in response to a force in a given direction. In some implementations, the first body 102 and the second body 104 can mechanically respond oppositely to one another in response to a change in temperature. In some cases, this can result in the circuit chip 100 as a whole being more mechanically robust.

Moreover, in some implementations, the first body 102, based on its auxetic structure, has a lower density than an alternative PPR body, such that the circuit chip 100 can be provided with reduced weight. For example, the first body 102 can have a lower density than the second body 104. As computing devices are increasingly integrated into weight-critical applications such as space vehicles, mobile devices, and Internet of Things (IoT) devices, the reduced weight provided by the use of NPR materials can be beneficial.

Referring again to FIG. 1, in some implementations, an optional second integrated circuit 105, having one or more circuit elements 108, is embedded in and/or on the first body 102. For example, the second integrated circuit 105 can include any or all of the types of circuit elements described above in reference to the integrated circuit 103. The circuit elements 108 of the second integrated circuit 105 can be coupled by interconnects. In some implementations, the integrated circuit 103 of the second body 104 is coupled to the second integrated circuit 105, e.g., by one or more connectors 110 (e.g., traces, wires, vias, and/or other interconnects, in some cases including one or more inter-substrate connections such as bump bonds) between a circuit element 106 of the integrated circuit 103 and a circuit element 108 of the second integrated circuit 105. Accordingly, electrical signals (e.g., currents and/or voltages) can be transferred between the bodies 102, 104.

In some implementations, one or more metal bodies 112a, 112b, 112c (referred to collectively as metal bodies 112) are provided in the first body 102. The metal bodies 112 have a high thermal conductivity so as to transfer heat through the first body 102 and promote thermal dissipation/cooling. In some implementations, as shown for metal body 112a, a metal body extends through the first body 102. In some implementations, as shown for metal body 112b, a metal body extends between the first body 102 and the second body 104, e.g., so as to transfer heat from the second body 104 to the first body 102 for dissipation/cooling. In some implementations, as shown for metal body 112, a metal body is connected to a metal heatsink 114 provided on an exterior of the first body 102. The heatsink 114, in some implementations, can instead or additionally be disposed elsewhere, e.g., on an exterior of the second body 104. Heat can transfer from the first body 102 to the metal body 112c (and, in some implementations, from the second body 104 to the metal body 112c), and from the metal body 112c to the heatsink 114 for dissipation. The metal bodies 112 can be provided in various orientations. In some implementations, the metal bodies 112 include metal pillars that extend vertically, e.g., in the same stacking direction 124 in which the first body 102 and the second body 104 are stacked on one another. The metal bodies 112 can be formed of one or more metals, e.g., copper, aluminum, titanium, a noble metal, and/or another metal.

In some implementations, the first body 102 and the second body 104 have similar thicknesses, e.g., thicknesses along the stacking direction 124. For example, each of the first body 102 and the second body 104 can have a thickness between 200 μm and 2 mm. In some implementations, respective thicknesses of the first body 102 and the second body 104 are within 50% of one another. In some implementations, the first body 102 is thinner than the second body 104. For example, the first body 102 can have a thickness less than 0.5 mm, less than 200 μm, or less than 100 μm. Other thicknesses are also within the scope of this disclosure.

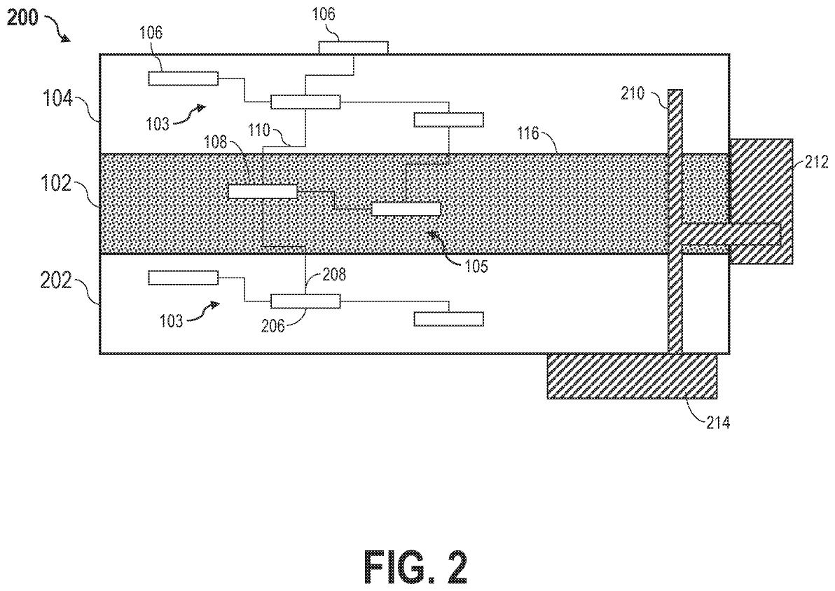

In some implementation, NPR and PPR materials are combined in a sandwich arrangement. As shown in FIG. 2, a circuit chip 200 includes a first body 102 and a second body 104, having characteristics as described for the corresponding elements of FIG. 1. In addition, the circuit chip 200 includes a third body 202 having a positive Poisson's ratio. The third body 202 can have any or all of the characteristics described for the first body 102. For example, the third body 202 can be rigid or flexible; can be a semiconductor wafer, semiconductor chip, or printed circuit board; and/or can host an integrated circuit 203 having circuit elements 206. In some implementations, the integrated circuit 203 is connected to the (optional) second integrated circuit 105 of the first body 102 by one or more connectors 208.

The first body 102, second body 104, and third body 202 can be stacked on one another with the first body 102 between the second body 104 and the third body 202. Accordingly, the first body 102, based on the structure associated with its negative Poisson's ratio, can receive heat transfer from both the second body 104 and the third body 202 to promote cooling. In some implementation, a metal body 210 extends between the three bodies 102, 104, 202, in some cases to a heatsink 212 disposed on the first body 102 and/or a heatsink 214 disposed on the second body 104 and/or third body 202, to further promote heat dissipation. The metal body 210 can have characteristics as described in reference to metal bodies 112.

Moreover, in some implementations, the first body 102 can improve the mechanical reliability of the entire circuit chip 200 by responding oppositely to the second body 104 and third body 202 in response to stresses/strains.

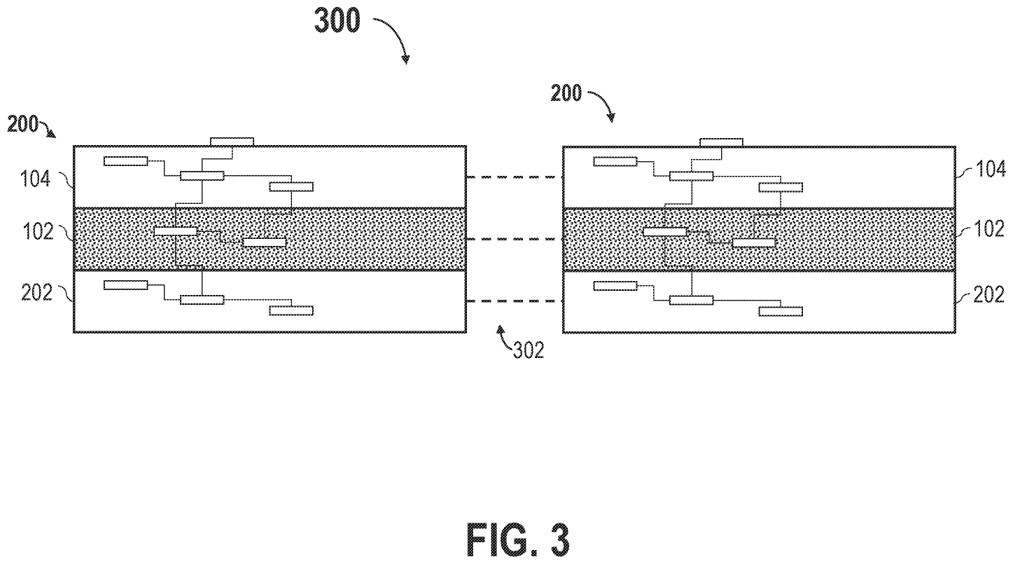

In some implementations, a combination of an NPR body and one or more PPR bodies (e.g., circuit chips 100, 200) forms a unit, and a device includes multiple such units. For example, as shown in FIG. 3, a circuit chip 300 includes a two circuit chips 200, each having characteristics as described in reference to FIG. 2. The circuit chips 200 are laterally spaced apart from one another. For example, the circuit chips 200 may be disposed on laterally spaced-apart portions of a common underlying substrate or circuit board. In this example, the circuit chips 200 are coupled by one or more connectors 302, such as wires, metal traces, cables, etc. For example, the connectors 302 can couple an integrated circuit in one of the circuit chips 200 to an integrated circuit in the other circuit chip 200, such as integrated circuits in the second bodies 104. Accordingly, signals can be exchanged between the circuit chips 200. The circuit chips 200 can respectively be, for example, two processors in communication with one another; a memory module and a memory controller; a memory device and a processor; a storage device and a processor; and/or any other combination of chip-integrated computing components. Although FIG. 3 illustrates multiple circuit chips 200 that have the stacked-sandwich structure of PPR/NPR/PPR, in some implementations other combinations of circuit chips are included, such as multiple circuit chips 100, or one or more circuit chips 100 with one or more circuit chips 200.

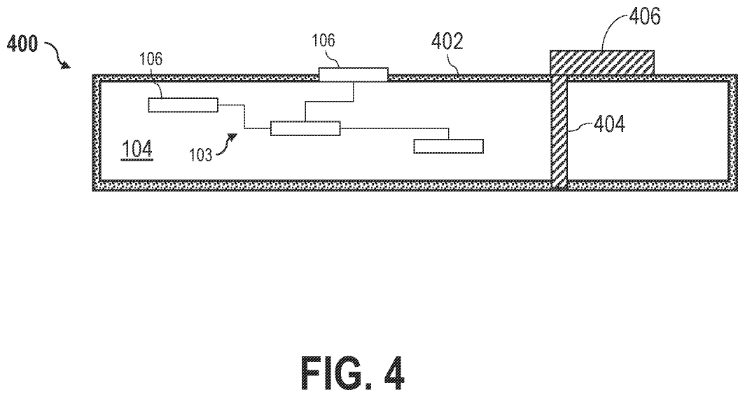

In some implementations, instead of or in addition to the stacked-body arrangement shown in FIGS. 1-3, a PPR material is coated with an NPR coating. For example, as shown in FIG. 4, a circuit chip 400 includes a PPR body 104 that can have any or all of the characteristics described for the second body 104 in reference to FIGS. 1-3. For example, an integrated circuit 103 having one or more circuit elements 106 can be embedded in and/or on the PPR body 104. A coating 402 having a negative Poisson's ratio coats the PPR body 104. The coating 402 can be formed of any one or more of the materials described in reference to the first body 102, e.g., a polymer, semiconductor, glass, ceramic, and/or glass-ceramic. In various implementations, the coating 402 can be formed by an AM process with the PPR body 104 as a substrate, and/or can be formed separately from the PPR body 104 (e.g., in an AM process and/or by a heat/pressure process as described in reference to FIGS. 6A-6C) and subsequently attached/bonded to the PPR body 104.

In some implementations, a metal body 404, such as a metal pillar, extends between the PPR body 104 and the coating 402 to transfer heat from the PPR body 104 to the coating 402. The metal body 404 can have characteristics as described for the metal bodies 112. In some implementations, the metal body 404 extends through the coating 402 to a metal heatsink 406 disposed on an exterior of the coating 402.

The coating 402 can be thin compared to the PPR body 104, e.g., can have a thickness that is less than 10%, less than 5%, or less than 2% a thickness of the PPR body 104. In some implementations, the coating 402 has a thickness less than 50 μm, less than 10 μm, or less than 1 μm. The coating 402 can coat one surface of the PPR body 104 (e.g., a surface on which one or more circuit elements 106 are formed) or can coat multiple surfaces. In some implementations, the coating 402 encapsulates the PPR body 104 by generally surrounding the PPR body 104.

In some implementations, the coating 402 is specifically a glass-ceramic material having a negative Poisson's ratio, e.g., ZnO—Al2O3-SiO2. The glass-ceramic coating 402 can be applied to the PPR body 104 (e.g., a silicon substrate) at elevated temperatures, e.g., 1200° C. The glass-ceramic coating 402 can be bonded to and/or fabricated on the underlying PPR body 104, exhibiting a high resistivity and protecting the PPR body 104 from environmental conditions such as moisture and contamination. In addition, the glass-ceramic coating 402 can exhibit a high electrical resistivity to electrically isolate integrated circuit(s) embedded in the PPR body 104.

The circuit chips described herein, such as those described in reference to FIGS. 1-4, can be included in various types of electronic devices to provide processing, storage, memory, sensing, signal transmission/reception, and/or other functionalities to the electronic devices. For example, the circuit chips can be integrated into smartphones, computers (e.g., mobile computers or desktop computers), tablets, wearable devices, IoT devices, cameras, vehicles such as autonomous and non-autonomous vehicles, and drones.

Various modifications will be apparent from the foregoing detailed description. For example, features described above in connection with different implementations may, in some cases, be combined in the same implementation. In some instances, the order of the process steps may differ from that described in the particular examples above.

Accordingly, other implementations are also within the scope of the claims.

What is claimed is:

1. A circuit chip, comprising:
a first body having a negative Poisson's ratio,
a second body having a positive Poisson's ratio, wherein the first body and the second body are stacked on one another and thermally coupled to one another, and
a first integrated circuit embedded in the second body.

2. The circuit chip of claim 1, wherein the first body and the second body are rigid.

3. The circuit chip of claim 1, wherein the first body comprises a semiconductor, a glass, a ceramic, or a glass-ceramic.

4. The circuit chip of claim 1, wherein the second body comprises a silicon substrate or a printed circuit board.

5. The circuit chip of claim 1, wherein the first body and the second body each have a substantially planar shape with a shortest dimension in a first direction, and
wherein the first body and the second body are stacked on one another in the first direction.

6. The circuit chip of claim 1, comprising a metal pillar extending through the first body.

7. The circuit chip of claim 6, wherein the metal pillar extends between the first body and the second body.

8. The circuit chip of claim 6, comprising a metal heatsink thermally coupled to the metal pillar.

9. The circuit chip of claim 1, comprising a second integrated circuit embedded in the first body.

10. The circuit chip of claim 9, comprising a connector arranged to electrically couple the first integrated circuit and the second integrated circuit.

11. The circuit chip of claim 1, comprising a third body having a positive Poisson's ratio,
wherein the first body is stacked between the second body and the third body.

12. The circuit chip of claim 11, wherein the second body and the third body are formed of a common material.

13. The circuit chip of claim 1, wherein the first body is porous.

14. The circuit chip of claim 1, wherein the first body and the second body are in contact with one another.

15. The circuit chip of claim 1, comprising:
a third body having a negative Poisson's ratio;
a fourth body having a positive Poisson's ratio, wherein the third body and the fourth body are stacked on one another and thermally coupled to one another, and
wherein the first body and the second body are spaced apart from the third body and the fourth body;
a second integrated circuit in the fourth body; and
one or more connectors electrically coupling the first integrated circuit to the second integrated circuit.

16. An electronic device comprising the circuit chip of claim 1, the electronic device comprising a smartphone, a computer, a tablet, a wearable devices, an Internet of Things device, a camera, a vehicle, or a drone.

17. A circuit chip, comprising:
a body having a positive Poisson's ratio;
an integrated circuit embedded in the body; and
a coating on the body, the coating having a negative Poisson's ratio.

18. The circuit chip of claim 17, wherein the coating comprises a glass-ceramic having the negative Poisson's ratio.

19. The circuit chip of claim 17, wherein the coating is porous.

20. The circuit chip of claim 17, comprising:
a metal heatsink; and
a metal pillar extending from the body, through the coating, and to the metal heatsink.
